(19) United States
(12) Patent Application Publication
(10) Pub. No.: US 2007/0246354 A1
(43) Pub. Date: Oct. 25, 2007

(54) Plasma systems with magnetic filter devices to alter film deposition/etching characteristics

(75) Inventors: Joseph Paul Ellul, San Jose, CA (US); Melvin C. Schmidt, San Jose, CA (US); Viktor Zekeriya, Atherton, CA (US); Rajiv L. Patel, San Jose, CA (US); Jack Kelly, San Jose, CA (US)

Correspondence Address: BLAKELY SOKOLOFF TAYLOR & ZAFMAN, 1279 OAKMEAD PARKWAY, SUNNYVALE, CA, 94085-4040, US

(73) Assignee: Maxim Integrated Products, Inc.

(21) Appl. No.: 11/407,441

(22) Filed: Apr. 19, 2006

(51) Int. Cl. C23C 14/00

(52) U.S. Cl. 204/298.02

(57) ABSTRACT

Plasma systems with magnetic filter devices to alter film deposition/etching characteristics by altering the effective magnetic field distribution. The magnetic filter devices are placed between the magnet or magnets and a target, typically a semiconductor wafer, and selected and configured to alter the magnetic field to obtain the desired processing results. For deposition, the magnetic filter may be chosen to provide more uniform deposition, to provide increased deposition rates at or adjacent the edges of a wafer to compensate for increased etching rates at the edges of a wafer in a subsequent etching or polishing process. For annealing and doping, the magnetic field may be altered to provide more uniform equivalent annealing or doping across the wafer. Various applications are disclosed.

### BACKGROUND OF THE INVENTION

1. Field of the Invention

The present invention relates to the field of glow-discharge deposition and etching systems.

2. Prior Art

Glow-discharge plasma deposition systems are used in the general IC industry for physical vapor deposition of metal and other films. A glow-discharge is a self-sustaining type of plasma, i.e., a partially ionized gas containing an equal number of negative and positive charges as well as some other number of non-ionized gas particles. In plasma systems, atoms are dislodged, or sputtered, from the surface of target material by collision with high energy particles. Some of the sputtered material arrives at the surface of a silicon wafer that faces the target and adheres to it there, thereby coating the surface with a film of sputtered material. Film thickness is in general proportional to deposition time and power. These metal films are used for a variety of purposes, including device interconnection, diffusion barrier, resistors, electrodes, etc.

The most commonly used systems in the industry today are magnetron sputtering systems. This type of sputtering increases the percentage of electrons that cause ionizing collisions by utilizing magnetic fields to help confine the electrons near the target surface. The plasma, sputtering target and wafer are typically contained in a deposition chamber. The stationary or rotating magnet is located immediately above the target. The magnet generates a plasma above the target and very close to the target face. The density of this plasma is relatively uniform. In turn, this translates to a deposited film on the wafer that is mostly uniform in thickness. Typical percentage standard-deviation (% STD) for a 0.5 μm thick aluminum layer is ˜0.5% (thickness range=150 Å). This non-uniformity is acceptable for most VLSI device applications. For the purposes of this work we shall refer to films with thickness greater than 0.1 μm as “thick films.”

Films needed for diffusion barriers, Schottky diodes, etc., may range in thickness from approximately 100 Å to 1000 Å. In this work, we refer to these films as “medium-thick films.” These films, such as TaN, TiN, CoSi₂, PdSi₂, etc., typically exhibit increased non-uniformity. This increased % STD is due to various effects, such as ab initio deposition and non-uniformities due to chamber issues (shields, dep rings, gas flow, wafer edge effects, etc.).

For 300 Å TiN, % STD may be as high as 2.5%, which translates to a range of ˜15%. One should note that although the actual thickness may not be increasing per se (15% of 300 Å is 45 Å), however, as a percentage of film thickness, and hence film properties, the % STD increases. Medium-thick films therefore exhibit an even greater non-uniformity in properties such as sheet resistance, conductivity, etc.

“Thin films,” that is, films whose thickness is less than 50 Å, in particular those films sputtered from multi-component targets, can exhibit % STD as high as 6% or more. The deposition of these very thin films is difficult to control without utilization of “averaging techniques,” such as wafer movement across a plasma region and very careful chamber design. Unfortunately, such systems are very expensive for general use in VLSI. Some of these systems in the industry are known generally as MRAM or Optical Systems.

An exemplary prior art glow-discharge plasma deposition system may be seen in FIG. 1. A vacuum chamber 20 is coupled to a cryogenic pump through port 22, and contains a wafer holder or chuck 24 for holding a semiconductor wafer 26. Above wafer holder 24 is a plate of target material 28 supported by a metal backing plate 30 that is insulated from the rest of the vacuum chamber. The wafer holder 24 and deposition shield 32 are electrically floating, with shield 34 and most of the vacuum chamber 20 being connected to a system ground. A target voltage is applied to the target 28, typically a combination of a high frequency AC and DC voltages. Above the metal backing plate 30, out of the vacuum chamber, is an array of magnets 35 mounted for rotation about a central axis 36 directing the deposition. In some glow-discharge plasma systems, the magnet or magnets may not rotate, and may be electro-magnets rather than permanent magnets. However their function is still the same, and the present invention applies equally to such systems. In that regard, rotation of the magnets as shown has the advantage of tending to average the deposition rate circumferentially around the wafer, leaving the primary, but not the only, variation in deposition rate as a radial variation, normally decreasing from the center of the wafer outward.

Glow-discharge plasma etching is the reverse of glow-discharge plasma deposition, the material being removed from a substrate rather than deposited, typically through a mask. While the effects of non-uniformity in etching rates across a wafer are usually not as significant as non-uniformities in deposition rates, still uniformity in etching rates is desirable to minimize etching time and minimize the time of exposure to the plasma etch of the layer below the layer being removed.

### BRIEF DESCRIPTION OF THE DRAWINGS

FIG. 1 schematically illustrates an exemplary prior art glow-discharge plasma deposition system.

FIG. 2 illustrates the magnetic profile near the target in a prior art glow-plasma deposition system of the general type shown in FIG. 1.

FIG. 3 illustrates the thick film deposition that results from the magnetic profile of FIG. 2 in a prior art glow-plasma deposition system of the general type shown in FIG. 1.

FIG. 4 shows measured sheet resistance contours of a deposited thin film on a 200 millimeter wafer in a prior art glow-plasma deposition system of the general type shown in FIG. 1.

FIG. 5 illustrates the use of a magnetic filter 38 in accordance with the present invention.

FIG. 6 illustrates the advantageous effect of a first order smoothing magnetic filter on the center region of a target in accordance with the present invention.

FIG. 7a illustrates the approximate non-uniformity of the film thickness contour based on the original magnetic field distribution with no magnetic filter in accordance with the present invention.

FIG. 7b illustrates the approximate thickness of the magnetic material to alter the film thickness proportionately.

FIG. 8a illustrates the deposition obtained without use of a magnetic filter in with the present invention.

FIG. 8b illustrates the effect of the magnetic filter on the resulting deposition thickness in accordance with the present invention.

### DETAILED DESCRIPTION OF THE PREFERRED EMBODIMENTS

In preferred embodiments, the present invention comprises the addition of a new device to a glow-plasma system to improve deposition uniformity in a commercial system designed for deposition of thick films. This new device is referred to herein as a “Magnetic Filter.” Such a Magnetic Filter can improve the as-deposited % STD of very thin, multi-component films by a factor of 5× or more, and add negligible system cost to the overall system and no additional cost in the operation of the system.

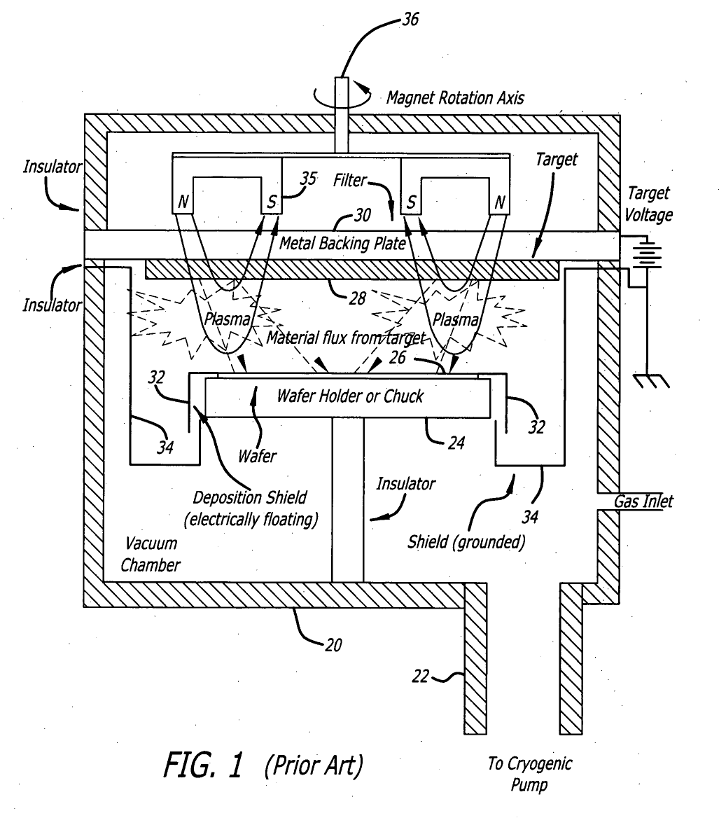

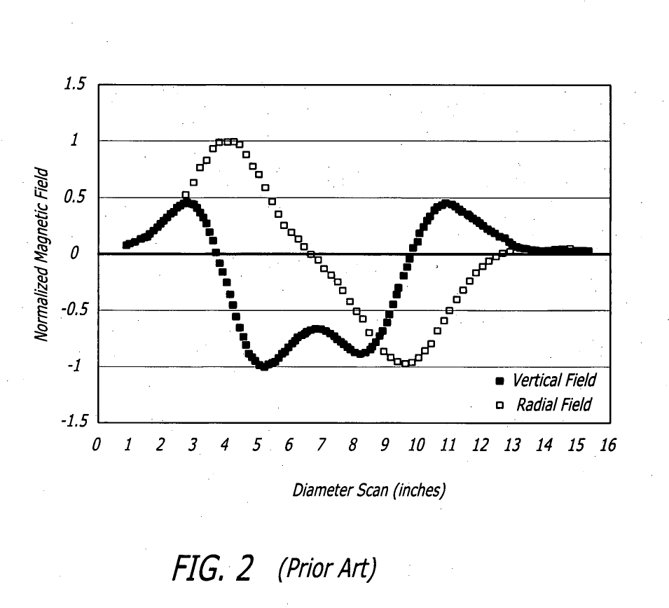

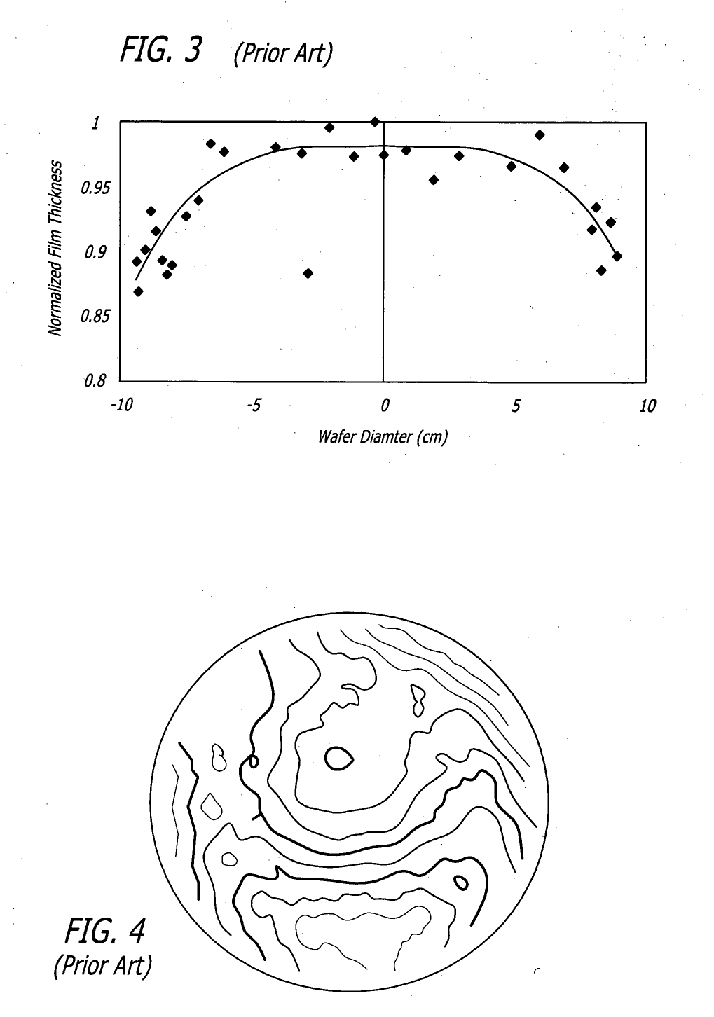

A prior art glow-plasma deposition system of the general type shown in FIG. 1 exhibits a magnetic profile near the target as illustrated in FIG. 2. This Figure shows the vertical field and radial field near the target, and relative to the wafer location. The thick film deposition that results is shown in FIG. 3. Here, the normalized film thickness is plotted against distance from the wafer center for a 200 millimeter wafer. It will be noted that the graph shows that film thickness drops sharply near the wafer edge, and that generally smaller, but still substantial variations are observed in the center region compared to the very large variation at the wafer edge. FIG. 4 in turn shows measured sheet resistance contours of a deposited thin film on a 200 millimeter wafer. These sheet resistance contours illustrate two problems with the prior art, namely a non-radial deposition and a high standard deviation, namely one standard deviation equals 4.5% of the average sheet resistance.

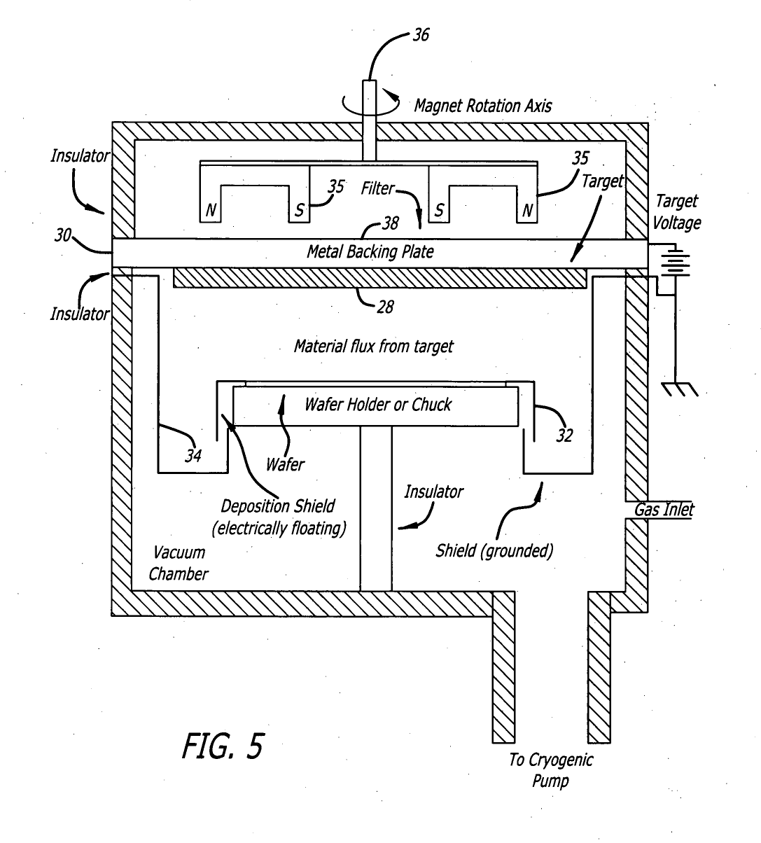

In accordance with the present invention, a magnetic filter 38 is placed between the metal backing plate 30 and the magnet 35, as may be seen in FIG. 5. The magnetic filter is fabricated from a magnetic material, such as by way of example, Co-Netic, though other materials may be used as desired, such as Netic. In general, the magnetic filter is fabricated from one or more sheets of a single soft magnetic material, that is, a material not commonly used for permanent magnets, and more preferably from a material that exhibits relatively low hysteresis, though magnetic filters of multiple materials may be used if desired. The thickness of the magnetic filter is varied, usually primarily radially, though can also be varied circumferentially as required, to achieve more uniform film deposition rates. In particular, the thickness of the magnetic filter versus position is determined empirically to provide the more uniform deposition rates desired. To a first order, the magnetic filter 38 is preferably thicker in regions of otherwise higher deposition rates (without the filter) and thinner or nonexistent in regions of lower deposition rates. The magnetic filter reduces the field strength in areas where the field strength would be particularly high by re-directing the field locally as well as globally. While the establishment of a magnetic filter 38 appropriate for providing film deposition thicknesses of the desired uniformity is an a mostly-empirical process, one very quickly develops a feel for the effect a change in the magnetic filter will make, so that one may develop a magnetic filter 38 substantially increasing the deposition rate uniformity in such glow-plasma deposition systems without undue experimentation.

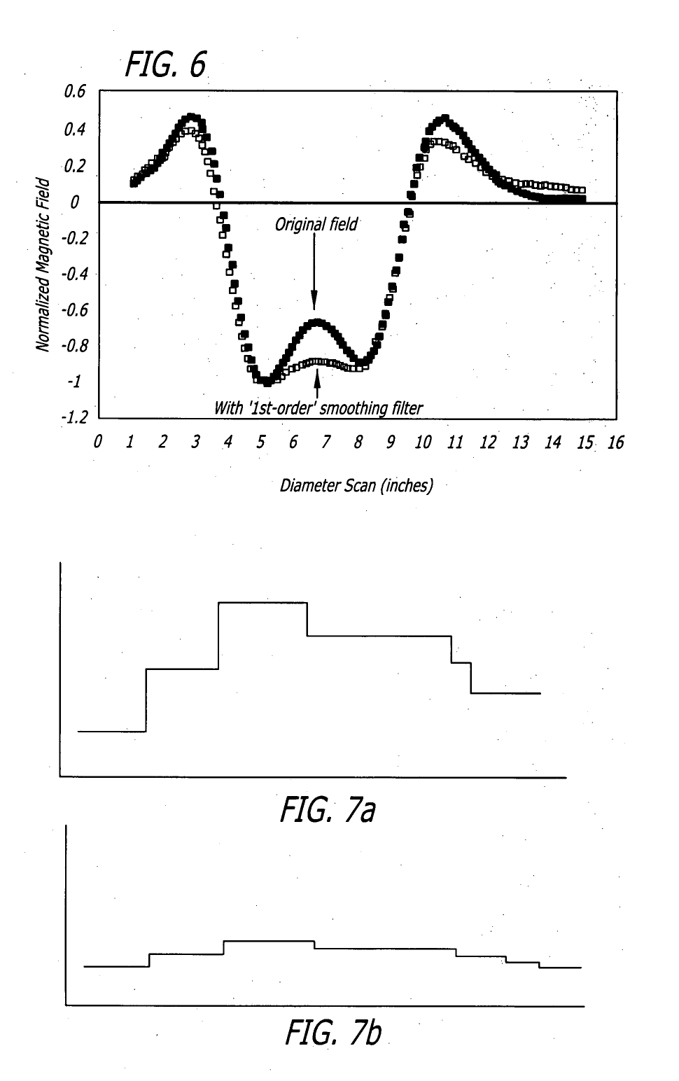

FIG. 6 shows the effect of a first-order, globally-smoothing magnetic filter on the center region of a target. This Figure shows the normalized magnetic field versus the diameter of the scan, showing the original vertical field of FIG. 2 and the field resulting from the first-order smoothing filter.

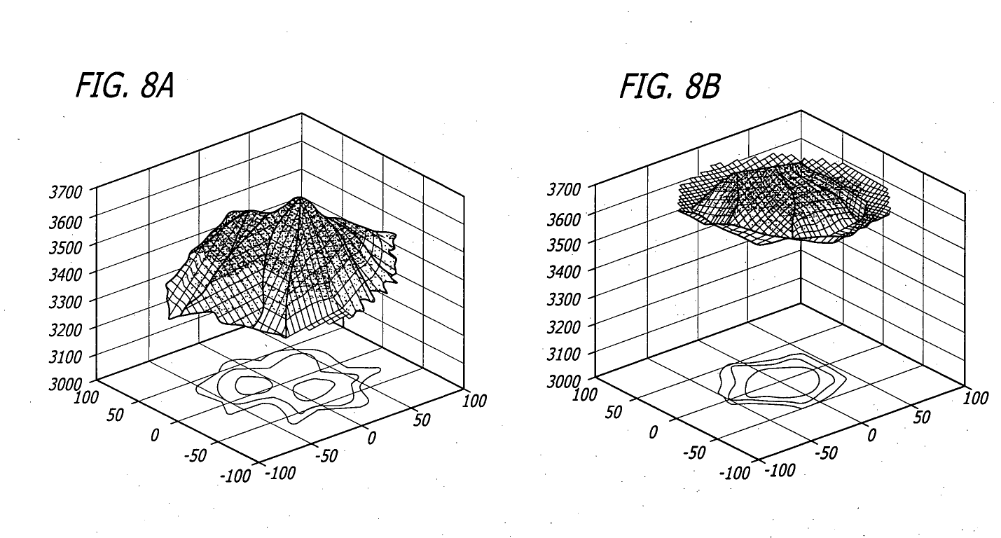

FIG. 7a illustrates the approximate non-uniformity of the film thickness contour based on the original magnetic field distribution. FIG. 7b, on the other hand, provides the approximate thickness and shape of the magnetic material to alter the film thickness proportionately. In this example, Co-Netic material was used for the magnetic filter with a maximum thickness of 40 mils. FIG. 8a illustrates the original deposition (without magnetic filter), showing relative peaks near the center, the strong roll off in thickness around the edges, and further illustrating the peculiar shape of the thickness contours. FIG. 8b shows the effect of the magnetic filter on the deposition thickness. In this particular example, two primary effects are realized. First, the peaks near the center are smoothed, and secondly, the outer edges are upturned again, as opposed to the substantial roll off thickness shown in FIG. 8a, resulting in a much reduced variation of deposition thickness across the wafer.

Thus in this particular application of the invention, one major benefit is the very low cost of adding a Magnetic Filter, which makes it an insignificant portion of the overall system cost. A second major and critical benefit is that the Magnetic Filter is positioned between the target and the magnet, and is external to the deposition chamber. As such, it is not deposition chamber intrusive, and therefore does not interfere directly with critical chamber process parameters such as pressure, temperature, electric potential, etc. Due to the latter, a third major benefit is that this technique can be applied equally well to all plasma systems for improved uniformity irrespective of their use as deposition or etch systems.

Other applications could require positioning of the Magnetic Filter within the magnetic field so as to cause a desired alteration of the magnetic field at a particular location in the space of interest. This may be inside or outside the plasma chamber.

The degree and type of magnetic filtering has been described in terms of global and local modifications of a generic plasma deposition production tool with a multi-component target for deposition of a sputtered thin film. Changes to plasma conditions due to the magnetic filter material have been shown in terms of normalized magnetic field strength changes. Deposited film improvements are shown in terms of contour maps and % STD. Although the initial, as-deposited film properties are highly non-linear and dependent on various properties, a magnetic filter can be deduced for any set of conditions with undue experimentation. It is thus possible to tailor film material parameters to suit particular application needs. In one particular case, this filtering technique is used for integrated circuit products. The degree and type of modification is not immediately apparent and cannot be deduced from present available knowledge published in the literature, but is determined empirically.

Although the data presented herein is for a composite film deposited in a generic, plasma production tool, specifically an Applied Materials metal deposition system, this technique is not limited to this composite film and this particular tool. Instead, the method is equally and similarly applicable to all plasma deposition, plasma doping and plasma etch tools that utilize either a plasma or ionized gasses to assist process conditions. Since the magnetic filter may not be intrusive to the process chamber, it is envisaged that other materials and tools can be altered and modified in a similar manner.

The present invention improves thin film as-deposited uniformity so that much more uniform thin films are manufacturable. It thus reduces the thin film cost per wafer, since more expensive deposition tools are not necessary. By improving product device uniformity across a wafer, device yield per wafer is also improved. When material trimming is necessary, the present invention reduces trim energy variability across a wafer, and hence reduces trim time. It also eliminates device yield loss particularly near the wafer edge. The present invention also reduces the film deposition rate during processing, and thus enables better wafer-to-wafer timing control for very thin processes (and generally very short deposition times), without reducing power supply set-points to levels where the power supply output is not well controlled.

In general, manufacturers of plasma systems try to optimize the magnet sets to improve within-wafer film uniformity. However there is a limit on the uniformity that can be achieved that way. The present invention takes the deposition (or etching) uniformity a step further to allow thin film deposition without the expensive and time-consuming task of attempting to re-engineer the entire magnet set and deposition chamber.

Other advantageous applications and effects that may be achieved by the present invention include:

a. Sputter rate changes for single or multi-component target. Globally changing the field changes the plasma voltage, which in turn changes the sputter rate of each element. This results in different sputtered-film compositions and equivalent parametric changes.

b. Plasma damage reduction. By creating a more uniform field globally across a wafer, one can optimize the process so that the plasma voltage is reduced and hence reduce plasma damage.

c. Radial field uniformity changes. An example is where one would want thicker deposition at the edge of a wafer to compensate for CMP (chemical mechanical polishing) increased erosion at the wafer edge. Similarly one can compensate for increased etch rates at the wafer edge.

d. Plasma annealing. Creating or modifying a non-uniform plasma for uniform equivalent annealing across a wafer.

e. Plasma doping. Creating or modifying a non-uniform plasma for uniform equivalent doping across a wafer.

f. Increased sputter yield from sputter targets, thereby reducing process cost-of-ownership.

In the claims to follow, systems in which the present invention is applicable are referred to as plasma systems, though are to be understood to include systems using an ionized gas, and are independent of the use of the system, such as, by way of example, for deposition, doping and annealing.

Thus while certain preferred embodiments of the present invention have been disclosed and described herein for purposes of illustration and not for purposes of limitation, it will be understood by those skilled in the art that various changes in form and detail may be made therein without departing from the spirit and scope of the invention.

What is claimed is:

1. A plasma system comprising:
a vacuum chamber;
a work piece holder within the chamber for holding a work piece to be processed;
an electrode adjacent a face of the work piece holder;
one or more magnets disposed adjacent a face of the electrode so that the electrode is between the magnets and the work piece holder to provide a magnetic field between the magnets and the work piece holder; and,
a magnetic filter disposed between the magnets and the electrode;
the magnetic filter being chosen and configured to alter the magnetic field between the electrode and a work piece on the work piece holder to alter work piece processing for achieving predetermined work piece processing results.

2. The system of claim 1 wherein the work piece is a semiconductor wafer.

3. The system of claim 2 wherein the electrode comprises a target material for sputter deposition, and wherein the magnetic filter is chosen and configured to alter the magnetic field between the target material and a semiconductor wafer on the work piece holder to provide more uniform deposition of target material on a surface of a semiconductor wafer.

4. The system of claim 2 wherein the electrode comprises a target material for deposition, and wherein the magnetic filter is chosen and configured to alter the magnetic field between the target material and a semiconductor wafer on the work piece holder to provide greater deposition of target material on a surface of a semiconductor wafer adjacent the edges of the work piece than in other areas of the semiconductor wafer.

5. The system of claim 2 wherein the magnetic filter is chosen and configured to alter the magnetic field between the electrode and a semiconductor wafer on the work piece holder to provide more uniform equivalent annealing of a surface of a semiconductor wafer.

6. The system of claim 2 wherein the magnetic filter is chosen and configured to alter the magnetic field between the target material and a semiconductor wafer on the work piece holder to provide more uniform equivalent annealing of a surface of a semiconductor wafer.

7. The system of claim 1 wherein the magnets are external to the vacuum chamber and disposed for rotation about an axis substantially aligned with an axis of the work piece holder.

8. The system of claim 7 wherein the magnetic filter is external to the vacuum chamber and between the magnets and the vacuum chamber.

9. The system of claim 1 wherein the magnets are external to the vacuum chamber and the magnetic filter is external to the vacuum chamber and between the magnets and the vacuum chamber.

10. The system of claim 1 wherein the magnetic filter is a Co-Netic filter.

11. A plasma system comprising:
a vacuum chamber;
a work piece holder within the chamber for holding a work piece on which deposition is to take place;
a plate of target material to be deposited having a face disposed adjacent a face of the work piece holder;
one or more magnets disposed adjacent a face of the target material so that the target material is between the magnets and the work piece holder; and,
a magnetic filter disposed between the magnets and the target material;
the magnetic filter being chosen and configured to alter the magnetic field between the target material and a work piece on the work piece holder to provide a more uniform deposition of the target material on a work piece than would be achieved without the magnetic filter.

12. The system of claim 11 wherein the work piece is a semiconductor wafer.

13. The system of claim 11 wherein the magnets are external to the vacuum chamber and disposed for rotation about an axis substantially aligned with an axis of the work piece holder.

14. The system of claim 13 wherein the magnetic filter is external to the vacuum chamber and between the magnets and the vacuum chamber.

15. The system of claim 11 wherein the magnets are external to the vacuum chamber and the magnetic filter is external to the vacuum chamber and between the magnets and the vacuum chamber.

16. The system of claim 11 wherein the magnetic filter is a Co-Netic filter.
